(19) United States
(12) Patent Application Publication
(10) Pub. No.: US 2015/0060742 A1
(43) Pub. Date: Mar. 5, 2015

(54) CONDUCTIVE PASTE USED FOR A SOLAR CELL ELECTRODE

(71) Applicant: E I DU PONT DE NEMOURS AND COMPANY, Wilmington, DE (US)

(72) Inventors: HOWARD DAVID GLICKSMAN, Durham, NC (US); YUMI MATSUURA, Kanagawa (JP)

(21) Appl. No.: 14/463,815

(22) Filed: Aug. 20, 2014

Related U.S. Application Data
(60) Provisional application No. 61/872,920, filed on Sep. 3, 2013.

(51) Int. Cl. H01B 1/22; H01L 31/18; H01L 31/0224

(52) U.S. Cl. CPC H01B 1/22; H01L 31/022425; H01L 31/18
USPC 252/514; 438/98

(57) ABSTRACT

A conductive paste used for a solar cell electrode comprising: (i) 60 wt % to 95 wt % of a silver powder, (ii) 0.1 wt % to 10 wt % of a glass frit, (iii) 3 wt % to 38 wt % of an organic medium, and (iv) 0.1 wt % to 5.0 wt % of a Ag—Bi composite powder, wherein the wt % are based on the total weight of the conductive paste.

### CROSS-REFERENCE TO RELATED APPLICATION

This application claims the benefit of U.S. Provisional Application No. 61/872,920, filed Sep. 3, 2013.

### FIELD OF THE INVENTION

The invention relates to a conductive paste to form a solar cell electrode.

### TECHNICAL BACKGROUND OF THE INVENTION

A conventional solar cell structure with a p-type base has a negative electrode that is typically on the front-side or sun side of the cell and a positive electrode on the back side. Most solar cells are in the form of a silicon wafer that has been metallized, i.e., provided with metal electrodes that are electrically conductive. Typically, a two-dimensional electrode grid pattern, i.e. “front electrode,” makes a connection to the n-side of the silicon, and a coating of aluminum on the opposite side (back electrode) makes connection to the p-side of the silicon. These contacts are the electrical outlets from the p-n junction to the outside load. The front electrodes of silicon solar cells are generally formed by screen-printing a paste. Typically, the paste contains electrically conductive particles, glass frit and an organic medium. After screen-printing, the wafer and paste are fired in air, typically at furnace set point temperatures of about 650-1000° C. for a few seconds to form a dense solid of electrically conductive traces. The organic components are burned away in this firing step. Also during the firing step, the glass frit and any added flux reacts with and etches through the anti-reflective coating and facilitates the formation of intimate silicon-electrode contact.

The glass frit and any added flux also provide adhesion to the substrate and aid in the adhesion of subsequently soldered leads to the electrode. Good adhesion to the substrate and high solder adhesion of the leads to the electrode are important to the performance of the solar cell as well as the manufacturability and reliability of the solar modules. For instance, US-2013-43440 A1 discloses conductive paste compositions comprising Li₂RuO₃ and results in improved adhesion while maintaining electrical performance.

### SUMMARY OF THE INVENTION

In one aspect, the present invention relates to a conductive paste used for a solar cell electrode comprising: (i) 60 wt % to 95 wt % of a silver powder, (ii) 0.1 wt % to 10 wt % of a glass frit, (iii) 3 wt % to 38 wt % of an organic medium, (iv) 0.1 wt % to 5.0 wt % of a Ag—Bi composite powder, wherein the wt % are based on the total weight of the conductive paste.

In another aspect, the present invention relates to a solar cell comprising an electrode formed from a conductive paste comprising: (i) 60 wt % to 95 wt % of a silver powder, (ii) 0.1 wt % to 10 wt % of a glass frit, (iii) 3 wt % to 38 wt % of an organic medium, (iv) 0.1 wt % to 5.0 wt % of a Ag—Bi composite powder, wherein the wt % are based on the total weight of the conductive paste, wherein the paste has been fired to remove the organic medium and formed the electrode.

In another aspect, the present invention relates to a solar cell electrode comprising silver powder, glass, and a Ag—Bi composite, wherein the bismuth as a metal is 0.03 to 3 wt % based on the weight of the solar cell electrode.

In another aspect, the present invention relates to a method of forming a solar cell electrode comprising steps of: (a) applying on a semiconductor substrate a conductive paste comprising: (i) 60 wt % to 95 wt % of a silver powder, (ii) 0.1 wt % to 10 wt % of a glass frit, (iii) 3 wt % to 38 wt % of an organic medium, and (iv) 0.1 wt % to 5.0 wt % of a Ag—Bi composite powder, wherein the wt % are based on the total weight of the conductive paste; (b) firing the applied conductive paste.

A solar cell electrode having sufficient adhesion can be formed by the present invention.

### BRIEF DESCRIPTION OF THE DRAWINGS

FIGS. 1A to 1F illustrate the fabrication of a solar cell.

### DETAILED DESCRIPTION OF THE INVENTION

### Conductive Paste

In one embodiment, the conductive paste used for a solar cell electrode comprises a silver powder, a glass frit, an organic medium, and a Ag—Bi composite powder.

### (i) Silver Powder

In one embodiment, the silver powder is in a flake form, a spherical form, a granular form, a crystalline form, other irregular forms and mixtures thereof. In another embodiment, the silver powder comprises coated silver particles that are electrically conductive. Suitable coatings include surfactants and phosphorous-containing compounds. Suitable surfactants include polyethyleneoxide, polyethyleneglycol, benzotriazole, poly(ethyleneglycol) acetic acid, lauric acid, oleic acid, capric acid, myristic acid, linolic acid, stearic acid, palmitic acid, stearate salts, palmitate salts, and mixtures thereof.

The mean particle size (D50) of the silver powder can be 0.1 μm to 10 μm in an embodiment, 0.5 to 8 μm in another embodiment, and 1 μm to 5 μm in still another embodiment. The silver powder with such particle diameter can be adequately dispersed in the organic binder and solvent, and smoothly applied by printing.

In this disclosure, mean particle size (D50) is obtained by measuring the distribution of the particle sizes by using a laser diffraction scattering method. Microtrac model 3500 is an example of the commercially-available devices that can be used for the measurement.

In one embodiment, the amount of silver powder in the conductive paste is 60 to 95 wt %, 85 to 95 wt % in another embodiment and 80 to 95 wt % in a further embodiment, based on the total weight of the conductive paste. So long as the amount of silver powder is 60 wt % or more, based on the total weight of the conductive paste, it is unlikely that the line width of a printed paste line expands due to sagging, etc. As long as the amount of silver powder is 95 wt % or less, based on the total weight of the conductive paste, the paste has a proper value of viscosity and hence has excellent printability. Consequently, as long as the amount of silver powder is in the range of 60 to 95 wt %, the conductive paste is capable of forming an electrode pattern with a fine line width.

### (ii) Glass Frit

The conductive paste comprises a glass frit. The glass frit is added so that the glass frit melts and adheres to the substrate at the relatively high temperature during the firing step. The chemical composition of the glass frit is not limited. Any glass frits suitable for use in electrically conducting pastes for electronic devises are acceptable. For example, a lead-tellurium-boron-oxide (Pb—Te—B—O) composition, a lead borosilicate composition, or a lead-free bismuth composition can be used. The lead-tellurium-boron-oxide composition may be crystalline, partially crystalline, amorphous, partially amorphous, or combinations thereof. In an embodiment, the Pb—Te—B—O composition may include more than one glass composition. In an embodiment, the Pb—Te—B—O composition may include a glass composition and an additional composition, such as a crystalline composition. The terms “glass” or “glass composition” will be used herein to represent any of the above combinations of amorphous and crystalline materials.

In an embodiment, the glass compositions may also include additional components such as silicon, silver, tin, bismuth, aluminum, titanium, copper, lithium, cerium, zirconium, sodium, vanadium, zinc, fluorine.

The lead-tellurium-boron-oxide (Pb—Te—B—O) may be prepared by mixing PbO, TeO₂, and B₂O₃ (or other materials that decompose into the desired oxides when heated) using techniques understood by one of ordinary skill in the art.

Such preparation techniques may involve heating the mixture in air or an oxygen-containing atmosphere to form a melt, quenching the melt, and grinding, milling, and/or screening the quenched material to provide a powder with the desired particle size. Melting the mixture of lead, tellurium, and boron oxides is typically conducted to a peak temperature of 800 to 1200° C. The molten mixture can be quenched, for example, on a stainless steel platen or between counter-rotating stainless steel rollers to form a platelet. The resulting platelet can be milled to form a powder. Typically, the milled powder has a D50 of 0.1 to 3.0 μm. One skilled in the art of producing glass frit may employ alternative synthesis techniques such as but not limited to water quenching, sol-gel, spray pyrolysis, quenching by splat cooling on a metal platen, or others appropriate for making powder forms of glass.

In an embodiment, the starting mixture used to make the Pb—Te—B—O may include (based on the weight of the total starting mixture): PbO that may be 25 to 75 wt %, 30 to 60 wt %, or 30 to 50 wt %; TeO₂ that may be 10 to 70 wt %, 25 to 60 wt %, or 40 to 60 wt %; B₂O₃ that may be 0.1 to 15 wt %, 0.25 to 5 wt %, or 0.4 to 2 wt %. In an embodiment, PbO, TeO₂, and B₂O₃ may be 80-100 wt % of the Pb—Te—B—O composition. In a further embodiment, PbO, TeO₂, and B₂O₃ may be 85-100 wt % or 90-100 wt % of the Pb—Te—B—O composition.

In one embodiment, the amount of the glass frit is 0.1 to 10 wt %, in another embodiment 0.5 to 8 wt % and in still another embodiment 1 to 5 wt %, based on the total weight of the conductive paste. Such amount of glass frit, provides an electrode with sufficient adhesion between the electrode and a substrate. In one embodiment, the softening point of the glass frit can be 390 to 600° C. When the softening point is in this range, the glass frit can melt properly to obtain the effects mentioned above.

(iii) Organic Medium

The inorganic components of the conductive paste are mixed with an organic medium to form viscous thick-film pastes or less viscous inks having suitable consistency and rheology for printing. A wide variety of inert viscous materials can be used as the organic medium. The organic medium can be one in which the inorganic components are dispersible with an adequate degree of stability during manufacturing, shipping and storage of the pastes or inks, as well as on the printing screen during a screen-printing process.

Suitable organic media have rheological properties that provide stable dispersion of solids, appropriate viscosity and thixotropy for printing, appropriate wettability of the substrate and the paste solids, a good drying rate, and good firing properties. The organic medium can contain thickeners, stabilizers, surfactants, and/or other common additives. One such thixotropic thickener is Thixatrol® (Elementis plc, London, UK). The organic medium can be a solution of polymer(s) in solvent(s). Suitable polymers include ethyl cellulose, ethylhydroxyethyl cellulose, wood rosin, mixtures of ethyl cellulose and phenolic resins, polymethacrylates of lower alcohols, and the monobutyl ether of ethylene glycol monoacetate. Suitable solvent includes terpineol, texanol, kerosene, dibutylphthalate, butyl carbitol, butyl carbitol acetate, hexylene glycol and alcohols with boiling points above 150° C., and alcohol esters. Other suitable organic medium components include: bis(2-(2-butoxyethoxy)ethyl adipate, dibasic esters such as DBE, DBE-2, DBE-3, DBE-4, DBE-5, DBE-6, DBE-9, and DBE 1B, octyl epoxy tallate, isotetradecanol, and pentaerythritol ester of hydrogenated rosin. The organic medium can also comprise volatile liquids to promote rapid hardening after application of the paste composition on a substrate.

The optimal amount of organic medium in the conductive paste is dependent on the method of applying the composition and the specific organic medium used. The instant conductive paste contains 3 to 38 wt % of organic medium, based on the total weight of the conductive paste.

If the organic medium comprises a polymer, the polymer typically comprises 8 to 15 wt % of the organic composition.

### (iv) Ag—Bi Composite Powder

In the present invention, a Ag—Bi composite powder is defined as a powder essentially composed of particles of both Ag and Bi in each particle, wherein such particles make up at least 90 wt % of the Ag—Bi composite powder, based on the total weight of the Ag—Bi composite powder. The Ag—Bi composite powder may be accompanied by other additional components such as Bi₂O₃.

The Ag—Bi composite powder is not a mixed powder of Ag powder particles and Bi powder particles.

As a result of the conductive paste containing the prescribed amount of Ag—Bi composite powder, the adhesion of electrodes formed from the conductive paste can be dramatically enhanced.

In one embodiment, the conductive paste comprises 0.1 wt % to 5.0 wt % of the Ag—Bi composite powder, wherein the wt % is based on the total weight of the conductive paste. In another embodiment, the conductive paste comprises 0.1 to 2.0 wt % of the composite powder. In a further embodiment, the conductive paste comprises 0.1 to 1.0 wt % of the Ag—Bi composite powder. The Ag—Bi composite powder content improves adhesion of the solar cell electrode to a semiconductor substrate.

The content of bismuth (Bi) as a metal is 0.01 to 0.5 wt % in an embodiment, 0.03 to 0.4 wt % in another embodiment and 0.1 to 0.3 wt % in still another embodiment base based on the total weight of the conductive paste.

The Ag—Bi composite powders in the conductive paste can be detected by an analysis of EDX Mapping (element distribution images) using a conventional SEM.

In one embodiment, the mean particle size (D50) of the Ag—Bi composite powder can be 0.1 to 5.0 μm in an embodiment, 0.5 to 3.0 μm in another embodiment, and 1.0 to 4.0 μm in still another embodiment. So long as the mean particle size (D50) of the Ag—Bi composite powder lies inside the above mentioned range, good printability can be obtained in coating the conductive paste.

In one embodiment, the surface area of the Ag—Bi composite powder is in the range of, for example, 0.5 to 1.2 m²/g as measured by the BET method. It is in the range of 0.7 to 1.0 m²g, in another embodiment. In one embodiment, the Ag—Bi composite powder has a density of 9 to 10.5 g/ml as measured by Helium pycnometry. In another embodiment, the density is in the range of 0.75 to 10.4 g/ml. The weight ratio of Ag/Bi in the Ag—Bi composite powder is 5/95-95/5. As long as the weight ratio of Ag/Bi lies inside the above mentioned range good adhesion can be obtained.

In one embodiment, the particles of the Ag—Bi composite powder are in the form of flakes, spheries, nodular-shaped (irregular-shaped) or any combinations thereof.

In one embodiment, the Ag—Bi composite powder is produced by a process comprising the steps of: a) generating an aerosol of droplets from a liquid wherein the liquid comprises a Ag metal precursor and a Bi metal precursor, b) moving the droplets in a carrier gas; and c) heating said droplets to remove liquid therefrom and form Ag—Bi composite powder. After c) heating, the Ag—Bi composite powder may be quenched. In more detail, Ag—Bi composite powder can in particular be produced by a pyrolysis process as disclosed in U.S. Pat. No. 6,277,169 B1 and US 2013/04659A1. One example of producing the Ag—Bi composite powder is described as follows.

—Example of Producing the Ag—Bi Composite Powder—

First, a precursor solution was prepared by adding nitric acid to a bismuth nitrate solution and heating the solution to about 45° C. After adding some additional water, solid silver nitrate was added to the solution and dissolved. Additional water was added so that the Ag—Bi is 10 wt % metal concentration. The relative amount of Ag to Bi is 91% Ag and 9% Bi by weight. An aerosol was then generated using air as the carrier gas flowing at 35 liters per minute and an ultrasonic generator with 28 ultrasonic transducers operating at 1.6 MHz. This aerosol was then sent through an impactor and then sent into a 3 zone furnace with the zones set at 900° C. After exiting the furnace, the aerosol temperature was quenched with air flowing at 750 liters per minute and the Ag—Bi composite powder was collected in a bag filter. This powder had a surface area of 0.94 m²/g, a density of 10.3 g/ml, and a powder size distribution of d10=0.58 μm, d50=0.97 μm, d90=2.05 μm and d95=2.55 μm.

A solar cell electrode formed by applying and firing the conductive paste on a semiconductor substrate comprises silver, glass, and Ag—Bi composite. The solar cell electrode comprises bismuth as a metal is 0.03 to 3 wt % based on the weight of the solar cell electrode.

### (v) Additives

As additives, in one embodiment, the conductive paste comprises a component selected from the group consisting of a lithium-ruthenium-oxide (Li₂RuO₃) powder, ion-exchanged Li₂RuO₃ powder and mixtures thereof. This component can improve the adhesion of electrodes made formed from the instant conductive paste. In one embodiment, the conductive paste comprises 0.03 to 5 wt % of this component, wherein the wt % is based on the total weight of the conductive paste. In another embodiment, the conductive paste comprises 0.06-3 wt % of this component. In still another embodiment, the conductive paste comprises 0.1-1 wt % of this component. In one embodiment, the component consists of Li₂RuO₃. The structure of Li₂RuO₃, as discussed in James and Goodenough; Journal of Solid State Chemistry 74, pp. 287-294, 1988, is composed in general of two adjacent, alternating layers, one layer containing only Li ions and the other containing both Ru and Li ions (ignoring the oxygen atoms).

In another embodiment, the component comprises ion-exchanged Li₂RuO₃. “Ion-exchanged Li₂RuO₃” is used herein to describe particles of Li₂RuO₃ in which Li atoms have been at least partially exchanged for Al, Ga, K, Ca, Mn, Fe, Mg, H, Na, Cr, Co, Ni, V, Cu, Zn, Ti or Zr atoms, or a combination thereof.

### (vi) Physical Properties of Conductive Paste

Viscosity

In one embodiment, the viscosity of the conductive paste is 200-500 Pa·s. In another embodiment, the viscosity of the conductive paste is 250-400 Pa·s. As long as the viscosity is 200 Pa·s or higher, there are few cases where, when the conductive paste is printed to form a line, the line width expands due to sagging, the height of the formed electrode is insufficient, or other problems arise. As long as the viscosity is 500 Pa·s or less, the conductive paste has a proper value of viscosity and hence has excellent printability. In the present invention, the viscosity of the conductive paste is a value obtained by measurement at 25° C., 10 rpm using a Brookfield HBT viscometer with a #14 spindle and a utility cup.

Inorganic Solids

The inorganic solids content of the conductive paste is calculated as the percentage (wt %) of inorganic solids relative to the total weight of the conductive paste. The inorganic solids typically consist of silver powder, glass frit and Ag—Bi composite powder. In one embodiment, the inorganic solids content is 60.2 to 95.4 wt %. In another embodiment, it is 85 to 93 wt %.

As long as the inorganic solids content is 60.2 wt % or more based on the whole conductive paste, it is unlikely that, when the paste is printed to form a line, the line width expands due to sagging, etc. As long as the inorganic solids content is 95.4 wt % or less based on the whole conductive paste, the paste has a proper value of viscosity to have excellent printability. Consequently, as long as the inorganic solids content is in the numeral-value range of 60.2 to 95.4 wt %, the conductive paste is capable of forming an electrode pattern with a small line width.

In cases where the inorganic solids content is lower than 60.2 wt %, there are instances where, when the conductive paste is printed to form a line, line width expansion or an insufficient line height results due to sagging. In cases where the inorganic solids content exceeds 95.4 wt %, there are instances where printing becomes difficult because of mask clogging.

### Preparation of the Conductive Paste

In one embodiment, the conductive paste can be prepared by mixing the above-mentioned silver powder, glass frit, organic medium, and Ag—Bi composite powder. In some embodiments, the inorganic materials are mixed first, and they are then added to the organic medium. In other embodiments, the silver powder, which is the major portion of the inorganics is slowly added to the organic medium. The viscosity can be adjusted, if needed, by the addition of solvents. Mixing methods that provide high shear are useful to disperse the particles in the medium.

### Formation of Solar Cell Electrodes

The conductive paste can be deposited, for example, by screen-printing, stencil-printing, plating, extrusion, ink-jet printing, shaped or multiple printing, or ribbons.

In this electrode-forming process, the conductive paste is first dried and then heated to remove the organic medium and sinter the inorganic materials. The heating can be carried out in air or an oxygen-containing atmosphere. This step is commonly referred to as “firing.” The firing temperature profile is typically set so as to enable the burnout of organic binder materials from the dried paste composition, as well as any other organic materials present. In one embodiment, the firing temperature is 700 to 950° C. The firing can be conducted in a belt furnace using high transport rates, for example, 100-500 cm/min, with resulting hold-up times of 0.03 to 5 minutes. Multiple temperature zones can be used to control the desired thermal profile.

In one embodiment, a semiconductor device is manufactured from an article comprising a junction-bearing semiconductor substrate and a silicon nitride insulating film formed on a main surface thereof. The instant conductive paste is applied (e.g., coated or screen-printed) onto the insulating film, in a predetermined shape and thickness and at a predetermined position. The instant conductive paste has the ability to penetrate the insulating layer, either partially or fully. Firing is then carried out and the paste reacts with the insulating film and penetrates the insulating film, thereby effecting electrical contact with the silicon substrate and as a result the electrode is formed.

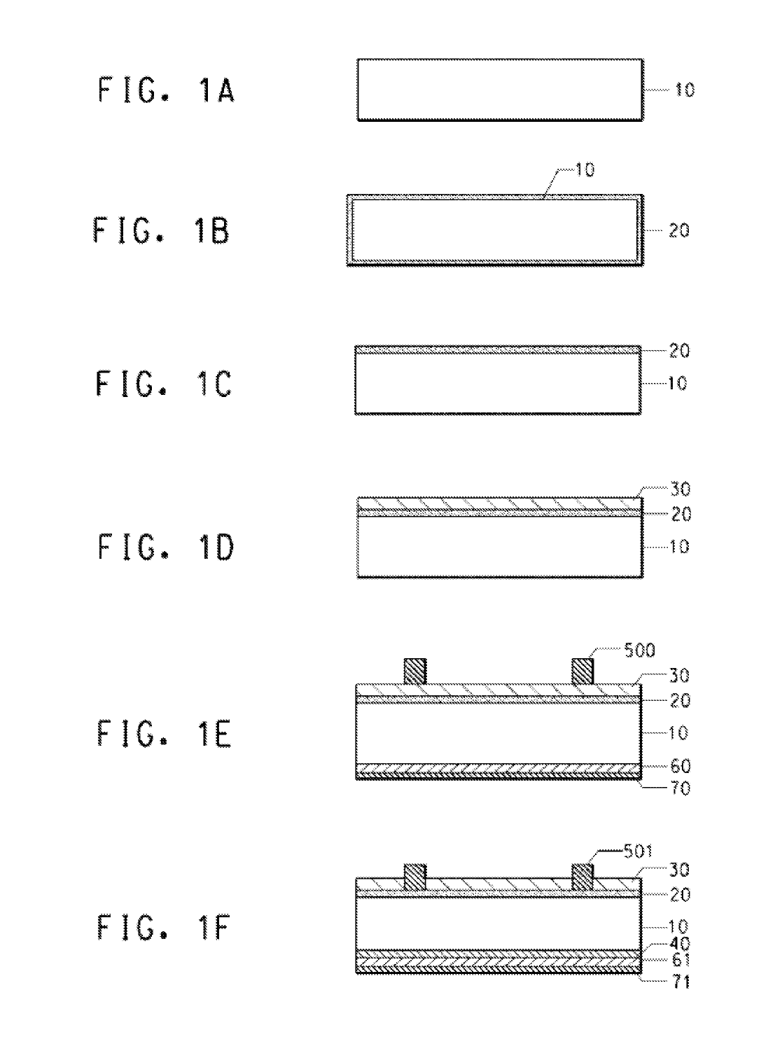

An example of this method of forming the electrode is described below in conjunction with FIGS. 1A-1F.

FIG. 1A shows a single crystal or multi-crystalline p-type silicon substrate 10.

In FIG. 1B, an n-type diffusion layer 20 of the reverse conductivity type is formed by the thermal diffusion of phosphorus using phosphorus oxychloride as the phosphorus source. In the absence of any particular modifications, the diffusion layer 20 is formed over the entire surface of the silicon p-type substrate 10. The depth of the diffusion layer can be varied by controlling the diffusion temperature and time, and is generally formed in a thickness range of about 0.3 to 0.5 microns. The n-type diffusion layer may have a sheet resistivity of several tens of ohms per square up to about 120 ohms per square.

After protecting the front surface of this diffusion layer with a resist or the like, as shown in FIG. 1C the diffusion layer 20 is removed from the rest of the surfaces by etching so that it remains only on the front surface. The resist is then removed using an organic solvent or the like.

Then, as shown in FIG. 1D an insulating layer 30 which also functions as an anti-reflection coating (ARC) is formed on the n-type diffusion layer 20. The insulating layer is commonly silicon nitride, but can also be a SiNₓ:H film (i.e., the insulating film comprises hydrogen for passivation during subsequent firing processing), a titanium oxide film, a silicon oxide film, or a silicon oxide/titanium oxide film. A thickness of about 700 to 900 angstrom of a silicon nitride film is suitable for a refractive index of about 1.9 to 2.0. Deposition of the insulating layer 30 can be by sputtering, chemical vapor deposition, or other methods.

Next, electrodes are formed. As shown in FIG. 1E, the conductive paste 500 is screen-printed to create the front electrode on the insulating film 30 and then dried, In addition, a back-side silver or silver/aluminum paste 70, and an aluminum paste 60 are then screen-printed onto the back side of the substrate and successively dried. Firing is carried out in an infrared belt furnace at a temperature range of approximately 750 to 950° C. for a period of from several seconds to several tens of minutes.

Consequently, as shown in FIG. 1F, during firing, aluminum diffuses from the aluminum paste 60 into the silicon substrate 10 on the back side thereby forming a p+ layer 40 containing a high concentration of aluminum dopant. This layer is generally called the back surface field (BSF) layer, and helps to improve the energy conversion efficiency of the solar cell.

Firing converts the dried aluminum paste 60 to an aluminum back electrode 61. The back-side silver or silver/aluminum paste 70 is fired at the same time, becoming a silver or silver/aluminum back electrode 71. During firing, the boundary between the back-side aluminum and the back side silver or silver/aluminum assumes the state of an alloy, thereby achieving electrical connection. Most areas of the back electrode are occupied by the aluminum electrode 61, owing in part to the need to form a p+ layer 40. Because soldering to an aluminum electrode is difficult, the silver or silver/aluminum back electrode 71 is formed over portions of the back side as an electrode for interconnecting solar cells by means of copper ribbon or the like. In addition, the front side conductive paste 500 sinters and penetrates through the insulating film 30 during firing, and thereby achieves electrical contact with the n-type layer 20. This type of process is generally called “fire through.” The fired electrode 501 of FIG. 1F shows the result of the fire through.

### EXAMPLES

The present invention is illustrated by, but is not limited to, the following examples.

The conductive paste was produced using the following materials.

Silver powder: Spherical Ag powder with mean particle diameter (D50) of 2.0 μm

Glass frit: Lead-Tellurium-Boron-Oxide glass comprising 30 to 50 wt % of PbO, 45 to 60 wt % of TeO₂, 5 to 8 wt % of Bi₂O₃, 0.25 to 2 wt % of Li₂O, and 0.25 to 2 wt % of B₂O₃.

Organic medium: a mixture of ethyl cellulose, wood rosin, texanol, butyl carbitol, a dispersant and a thickner.

Ag—Bi composite powder: Mean particle diameter (D50) was 1.0 μm, weight ratio of Ag/Bi was 30/70, 50/50, 70/30, or 90/10 as shown in Table 1

Li₂RuO₃ powder with mean particle diameter (D50) of 0.8 μm.

A conductive paste was prepared using the following procedure. An organic binder (polymer) and an organic solvent were mixed in a glass vial for 48 hours at 100° C. to form an organic medium. Silver powders, glass frit, Ag—Bi composite powders and Li₂RuO₃ powders were added to the organic medium and mixed further for 5 minutes by a planetary centrifugal mixer to form a conductive paste. When well mixed, the conductive paste was repeatedly passed through a 3-roll mill at progressively increasing pressures from 0 to 400 psi. and the gap of the rolls was adjusted to 1 mil.

The conductive paste was screen printed onto 6″×6″ 65-ohm poly-crystalline Si substrates with about 70 nm of SiNₓ antireflective coating on the front side. The pattern consisted of 70 fingers (50 microns wide) and 2 busbars (2.0 mm wide).

On the back side of the substrate, a conductive paste was coated for solder connection by screen printing and dried. The conductive paste contained silver powders, glass frits and a resin binder. The drying temperature of the pastes was 150° C. The resulting substrate was subjected to simultaneous firing of the coated pastes in an infrared furnace with a peak temperature of 750° C. and IN-OUT for about 1 min to obtain the desired test sample solar cell electrode.

Adhesion of the electrode was measured by the following procedures. A copper ribbon coated with a Sn/Pb solder (Ulbrich Stainless Steels & Special Metals, Inc.) was dipped into a soldering flux (Kester-952s, Kester, Inc.) and then dried for five seconds in air. Half of the solder coated copper ribbon was placed on the bas electrode and soldering was done by a soldering system (SCB-160, SEMTEK Corporation Co., Ltd.). The soldering iron setting temperature was 190 to 240° C. and the actual temperature of the soldering iron at the tip was from 105 to 215° C. measured by K-type thermocouple. The rest part of the copper ribbon which did not adhere to the has electrode was horizontally folded and pulled at 120 mm/min by a machine (Peel Force 606, MOGRL Technology Co., Ltd.). The strength (Newton, N) at which the copper ribbon was detached was recorded as the solder adhesion.

Adhesion of the solar cell electrode improved in Example 1 to 7 where the conductive paste contained the Ag—Bi composite powder with different amount compare to Comparative example (Com. Ex.) 1 where the conductive paste contained no Ag—Bi composite powder as shown in Table 1.

TABLE 1
(wt %)

| | | Com. | | | | | | | |
|---|---|---|---|---|---|---|---|---|---|
| | | Ex. 1 | Ex. 1 | Ex. 2 | Ex. 3 | Ex. 4 | Ex. 5 | Ex. 6 | Ex. 7 |
| Ag powder | | 88.8 | 88.7 | 88.5 | 88.7 | 88.5 | 88.4 | 88.4 | 88 |
| Glass frit | | 1.8 | 1.8 | 1.8 | 1.8 | 1.8 | 1.8 | 1.8 | 1.8 |
| Organic medium | | 9.2 | 9.3 | 9.3 | 9.3 | 9.3 | 9.2 | 9.2 | 9.2 |
| Ag—Bi | 30/70 | 0 | 0.1 | 0.3 | 0 | 0 | 0 | 0 | 0 |
| composite | 50/50 | 0 | 0 | 0 | 0.1 | 0.3 | 0.5 | 0 | 0 |
| powder | 70/30 | 0 | 0 | 0 | 0 | 0 | 0 | 0.5 | 0 |
| (Ag/Bi) | 90/10 | 0 | 0 | 0 | 0 | 0 | 0 | 0 | 0.9 |
| | (Bi content) | 0 | 0.07 | 0.21 | 0.05 | 0.15 | 0.25 | 0.15 | 0.09 |

| | | | | | | | | |
|---|---|---|---|---|---|---|---|---|
| Li₂RuO₃ powder | 0.1 | 0.1 | 0.1 | 0.1 | 0.1 | 0.1 | 0.1 | 0.1 |
| Total | 100.0 | 100.0 | 100.0 | 100.0 | 100.0 | 100.0 | 100.0 | 100.0 |
| Adhesion (N) | 1.6 | 1.9 | 2 | 2 | 2.2 | 2.6 | 2.2 | 2.1 |

We claim:

1. A conductive paste used for a solar cell electrode comprising,
(i) 60 wt % to 95 wt % of a silver powder,
(ii) 0.1 wt % to 10 wt % of a glass frit,
(iii) 3 wt % to 38 wt % of an organic medium, and
(iv) 0.1 wt % to 5.0 wt % of a Ag—Bi composite powder,
wherein the wt % are based on the total weight of the conductive paste.

2. The conductive paste of claim 1, where the content of bismuth (Bi) as a metal is 0.01 wt % to 0.5 wt %.

3. The conductive paste of claim 1, further comprises a component selected from the group consisting of Li₂RuO₃ powder, ion-exchanged Li₂RuO₃ powder and mixtures thereof.

4. The conductive paste of claim 1, wherein the glass frit is a lead-tellurium-boron-oxide.

5. The conductive paste of claim 1, wherein the weight ratio of Ag/Bi in the Ag—Bi composite powder is from 95/5 to 5/95.

6. The conductive paste of claim 1, wherein the Ag—Bi composite powder is produced by a process comprising the steps of: a) generating an aerosol of droplets from a liquid wherein the liquid comprises a Ag metal precursor and a Bi metal precursor; b) moving the droplets in a carrier gas; and c) heating said droplets to remove liquid therefrom and form the Ag—Bi composite powder.

7. A solar cell comprising an electrode formed from the conductive paste of claim 1, wherein the conductive paste is fired to remove the organic medium to form the electrode.

8. A method of forming a solar cell electrode comprising steps of:
(a) applying on a semiconductor substrate a conductive paste comprising,
(i) 60 wt % to 95 wt % of a silver powder,
(ii) 0.1 wt % to 10 wt % of a glass frit,
(iii) 3 wt % to 38 wt % of an organic medium, and
(iv) 0.1 wt % to 5.0 wt % of a Ag—Bi composite powder,
wherein the wt % are based on the total weight of the conductive paste;
(b) firing the applied conductive paste.

9. A solar cell electrode comprising, silver, glass, and a Ag—Bi composite, wherein the bismuth as a metal is 0.03 to 3 wt % based on the weight of the solar cell electrode.
